(19) United States
(12) Patent Application Publication
(10) Pub. No.: US 2023/0402701 A1
(43) Pub. Date: Dec. 14, 2023

(54) CIRCUIT BOARD ARRANGEMENT AND ENERGY STORAGE DEVICE

(71) Applicants: Diehl AKO Stiftung & Co. KG, Wangen (DE); Diehl Advanced Mobility GmbH, Zehdenick (DE)

(72) Inventors: Mateusz Kurpiel, Wangen (DE); Ingo Weber, Potsdam (DE); Markus Kohler, Nürnberg (DE); Tejas Harish Navsariwala, Berlin (DE); Artur Dick, Strausberg (DE); Kian Mahdjour, Berlin (DE); Silke Abreder, Sauldorf (DE); Artur Schütz, Wangen (DE); David Jäger, Lindenberg (DE); Bernhard Lutz, Wangen (DE)

(21) Appl. No.: 17/941,193

(22) Filed: Sep. 9, 2022

(30) Foreign Application Priority Data
Jun. 10, 2022 (DE) 10 2022 114 652.9

(51) Int. Cl. H01M 50/284; H01M 50/262; H01M 50/342; H01M 10/48; H01M 10/42; H05K 1/11

(52) U.S. Cl. CPC H01M 50/284; H01M 50/262; H01M 50/3425; H01M 50/249; H01M 10/425; H05K 1/111; H01M 2220/20; H01M 10/486

(57) ABSTRACT

A circuit board arrangement for a cell contacting system for contacting energy storage cells of an energy storage device, in particular an energy storage device for a vehicle, includes a circuit board on which open-loop and/or closed-loop control electronics for open-loop and/or closed-loop control of the energy storage device and/or the respective energy storage cell are located. An additional circuit board includes at least one sensor element. The circuit board and the additional circuit board are electrically connected to each other by a contacting device. The additional circuit board is spaced apart from the circuit board and the spacing between the additional circuit board and the circuit board is bridged by the contacting device. An energy storage device, in particular an energy storage device for a vehicle, is also provided.

### CROSS-REFERENCE TO RELATED APPLICATION

This application claims the priority, under 35 U.S.C. § 119, of German Patent Application DE 10 2022 114 652.9, filed Jun. 10, 2022; the prior application is herewith incorporated by reference in its entirety.

### FIELD AND BACKGROUND OF THE INVENTION

The present invention relates to a circuit board arrangement for a cell contacting system for contacting energy storage cells of an energy storage device, in particular an energy storage device for a vehicle, including a circuit board on which open-loop and/or closed-loop control electronics for open-loop and/or closed-loop control of the energy storage device and/or the respective energy storage cell are located, and an additional circuit board including at least one sensor element, wherein the circuit board and the additional circuit board are electrically connected to each other by a contacting device. The invention also relates to an energy storage device, in particular an energy storage device for a vehicle in the automotive sector, including a plurality of energy storage cells disposed in a row.

A central point in the development of electrically powered means of transport, for example electric vehicles, is energy storage. This requires energy storage devices with a high power density and energy density. Energy storage devices are regularly formed of a plurality of individual energy storage cells (for example lithium ion battery cells) that are electrically connected to each other. Energy storage devices usually require temperature management to ensure their operation in an optimized temperature range. The energy storage cells usually have a narrow operating temperature range (for example between +15° C. and +45° C.). The functional safety, service life and cycle stability of the energy storage cell and thus also the functional safety of the entire energy storage device depend significantly on the energy storage cell not leaving this range. If the temperature exceeds a critical level, a so called “thermal runaway” occurs. In the case of thermal runaway, an unstoppable chain reaction is set in motion. The temperature rises extremely within milliseconds and the energy stored in the energy storage cell is released suddenly. In this way, temperatures of over 1000° C. can occur. The contents of the energy storage device become gaseous and a fire occurs that is difficult to extinguish by conventional measures. The danger of a thermal runaway starts at a certain temperature (for example 60° C.) and becomes extremely critical at a further temperature threshold (for example 100° C.). As a result, energy storage devices, especially energy storage devices for electric vehicles, use an energy storage device management system that not only provides open loop or closed loop control of the charging and discharging behavior of the energy storage cells, but also takes measures with regard to temperature management and emergency management in the event of a thermal runaway. In order to ensure a targeted escape of gases in the event of a thermal runaway, the gas tightly sealed energy storage cells can have degassing openings. The degassing openings can, for example, be configured as predetermined breaking points which allow gases to escape from the interior of the energy storage cell to the surrounding environment above a certain internal pressure. The escaping gases may contain electrolytes that can react with water to form hydrofluoric acid. In order to reduce the danger to surrounding components and/or individuals, such gases must be discharged in a controlled and targeted manner.

In order to provide the electrical connection of the energy storage cells, energy storage devices have so called cell connectors that electrically connect two or more poles of two or more energy storage cells, depending on the circuit type. In a series circuit, for example, the anode of one energy storage cell is connected to the cathode of another energy storage cell. In order to be able to monitor and control the state of charge of each energy storage cell, each cell connector can be electrically connected to the open loop and/or closed loop control electronics of the energy storage device. This allows the cell voltage of each individual energy storage cell to be measured and the state of charge of each particular energy storage cell to be deduced by the cell voltage. Furthermore, sensors, for example temperature sensors for monitoring the surface temperature of the energy storage cells, can also be provided, which are connected to the open loop and/or closed loop control electronics. In previous solutions, the open loop and/or closed loop control electronics are located in an independent module.

### DESCRIPTION OF THE RELATED ART

German Patent Application DE 10 2007 063 178 A1 discloses a battery with a heat conducting plate for controlling the temperature of the battery. The battery includes a plurality of interconnected individual cells. The heat conducting plate has holes and/or incisions in the region of the poles of the individual cells, through which the poles of the individual cells protrude in or out. The heat conducting plate is disposed between the individual cells and contacting elements placed on the poles. Electrical cell connectors and/or a cell connector circuit board are provided as contacting elements for the electrical connection of the poles of the individual cells. Furthermore, elastic elements and/or contacting elements may be located on the upper side of the heat conducting plate. This sequence of these individual layers must be clamped to the individual cells by screws during the assembly process. The assembly is therefore time consuming.

German Patent Application DE 10 2009 046 385 A1, corresponding to U.S. Patent Application Publication No. 2013/0059175 A1, discloses a battery with a degassing system. The degassing system is located on the side opposite the poles of the battery cells. A base plate provided specially for this purpose is provided there, with passages for degassing openings and a collection basin for collecting the gases from the battery cells.

German Patent Application DE 10 2012 219 784 A1 discloses a battery module including a gas channel, a printed circuit board and a battery module housing which accommodates a plurality of battery cells. The gas channel is formed by a U profile with through openings to the degassing openings of the battery cells and by a printed circuit board closing the U profile on the side facing away from the degassing openings. The printed circuit board thus forms a wall of the gas channel and can come into direct contact with the gas when gas escapes from a gas outlet opening of a battery cell. During assembly, the printed circuit board is attached directly to the busbars. The U profile is not directly connected to the busbars. The disadvantage of this arrangement is that escaping gas can destroy the unprotected circuit board. In this case, open loop and/or closed loop control of the battery module is no longer ensured. Furthermore, no active temperature control of the battery cell surface or of the cell connectors is provided.

European Patent Application EP 3 316 384 A1, corresponding to U.S. Pat. No. 11,127,990 B2, discloses a circuit board arrangement as described above. A rigid circuit board for open loop and/or closed loop control electronics is provided, to the surface of which there are directly applied cell connectors for connecting the energy storage cells. Due to this direct connection of the cell connectors to the open loop and/or closed loop control electronics, a direct heat transfer from the electrical connections of the energy storage cells to the open loop and/or closed loop control electronics takes place. Such an arrangement leads to unavoidable measurement deviations in the voltage and temperature measurement. Furthermore, a C shaped flexible printed circuit board carrying a temperature sensor element is fixed to the rigid circuit board. The flexible printed circuit board extends through a slot shaped through opening in the rigid circuit board. The construction is complex and costly, both in terms of the production of the individual parts and in terms of final assembly.

### SUMMARY OF THE INVENTION

It is accordingly an object of the invention to provide a circuit board arrangement for a cell contacting system for energy storage cells and an energy storage device, which overcome the hereinafore-mentioned disadvantages of the heretofore-known arrangements and devices of this general type and which simplify an assembly effort but are nevertheless operationally reliable.

With the foregoing and other objects in view there is provided, in accordance with the invention, a circuit board arrangement for a cell contacting system for contacting energy storage cells of an energy storage device, in particular an energy storage device for a vehicle, comprising a circuit board on which open-loop and/or closed-loop control electronics for open-loop and/or closed-loop control of the energy storage device and/or the respective energy storage cell are located, and an additional circuit board including at least one sensor element, wherein the circuit board and the additional circuit board are electrically connected to each other by a contacting device. According to the invention, the additional circuit board is spaced apart from the circuit board of the open-loop and/or closed-loop control electronics in each case with respect to their main surfaces, wherein the spacing between the additional circuit board and the circuit board is bridged by the contacting device. The additional circuit board for example firstly allows the temperature of the surface of the energy storage cell to be measured by a sensor element located there. Secondly, other physical and/or chemical parameters can also be measured in the region of the energy storage cells by using sensor elements fitted to the additional circuit board. Since the additional circuit board is spaced apart from the circuit board and the spacing between the additional circuit board and the circuit board is bridged only by the contacting device, it is possible to provide a separating wall between the circuit board and the additional circuit board, with the result that the circuit board can be positioned, for example, outside a degassing channel, whereas the additional circuit board can be positioned inside a degassing channel.

For this purpose, the main surfaces of the circuit board and the additional circuit board can preferably be disposed vertically offset.

The additional circuit board can be plate-shaped, like a conventional circuit board in particular.

The at least one sensor element can advantageously have a thermally conductive, preferably elastic, contact element through which the sensor element can be contacted with the surface of an energy storage cell. This is advantageous particularly in the case of a temperature sensor element since the contact element is thermally conductive. Furthermore, contacting of the surface of the energy storage cell is improved due to the elasticity of the contact element. In addition, manufacturing tolerances can be compensated for during assembly due to the elasticity.

The fact that the additional circuit board and the circuit board are each elongate and run adjacent to each other means that a plurality of sensor elements can be positioned along the additional circuit board, along the course of the circuit board and/or along the surface of the energy storage cell using a single component. As a result, assembly can be simplified.

According to an expedient embodiment of the present invention, a support structure mountable on the energy storage device or its energy storage cells is provided, wherein the support structure has a first side facing the energy storage device in the installed state and a second side facing away from the energy storage device in the installed state, the circuit board is fastened to the second side of the support structure and the additional circuit board is positioned on the first side of the support structure. The support structure is preferably a profiled structure. The support structure shields the circuit board, in particular the circuit board on which the open-loop and/or closed-loop control electronics of the energy storage device or the energy storage cells is located, from the surface of the energy storage cells, whereas the additional circuit board is positioned on the side of the support structure facing the energy storage device or the energy storage cells. Spacers are preferably provided between the first side of the support structure and the additional circuit board.

The spacers can advantageously have at least one connection element, in particular a snap connection element, on the side facing the support structure or the side facing the additional circuit board, or preferably two connection elements, in particular two snap connection elements, on the side facing the support structure and the side facing the additional circuit board and can be connected to the support structure and/or the additional circuit board. This allows particularly simple assembly of the additional circuit board.

The contacting devices are preferably conductor bars protruding from the additional circuit board which pass through the circuit board, preferably in the region of a through-opening in the circuit board or preferably in the form of a press-fit arrangement.

The conductor bars can be contacted on the side of the circuit board facing away from the additional circuit board, preferably with the aid of an in particular plug-mountable contacting strip.

According to a particular embodiment of the present invention, the support structure can be connected to cell connectors provided for electrically connecting the energy storage cells to form a unit that can be mounted collectively. This embodiment allows the support structure, the circuit board, the additional circuit board and the cell connectors to be prefabricated as a unit that can be mounted collectively, so that the entire unit only has to be fixed, in particular welded, to the energy storage cells of the energy storage device by the cell connectors during assembly.

The support structure can preferably have a degassing channel integrated into the support structure and/or at least one temperature control channel integrated into the support structure. The at least one degassing channel and the at least one temperature control channel thus form an integral part of the support structure and thus an integrated compact, scalable cell contacting system. As a result of the fact that both the at least one temperature control channel and the degassing channel are an integral part of the support structure, the assembly effort required to complete an energy storage device can be significantly reduced. In addition, the functional reliability of the energy storage device is increased and a reduction in the required installation space is achieved. The degassing channel enables a targeted removal of hot gases during a thermal runaway of the energy storage device. Compared to conventional embodiments, the number of parts can be reduced.

Advantageously, the at least one degassing channel and the at least one temperature control channel are each molded into the support structure. This means that the support structure is configured as a single component and can be produced in a single manufacturing step. In addition, a higher functional safety is achieved due to the one piece configuration without connection points of the various channels.

It is expedient that the support structure has a wall delimiting the degassing channel, the side of the wall opposite the degassing channel serving as a mounting base for further components. The aforementioned side of the wall can thus serve for the assembly of further components of the cell contacting system, for example for assembly of the circuit board and the additional circuit board. The wall therefore fulfils a dual function. The circuit board is protected from thermal and/or chemical influences by the wall.

Preferably, the wall extends between two temperature control channels.

According to an advantageous embodiment, the inner side of the degassing channel has a protective layer, in particular protecting against heat and/or abrasive media and/or chemical influences (for example by acids). In addition, the underside of the corresponding temperature control channel can also have a protective layer.

The protective layer can be an applied coating (for example a liquid, curable coating, for example lacquers with the addition of ceramic particles, foamed and cured coating or for example a powder coating) or a layer placed on and/or bonded to the wall or the wall portion in question (for example a mica sheet, a ceramic fiber mat, a glass fiber mat, a carbon mat or a cork sheet).

The at least one temperature control channel as well as temperature control lines connecting to the at least one temperature control channel are preferably sealed at all interfaces.

The wall extends expediently between two or at least two temperature control channels. The temperature control channels are preferably each located in the outer region of the support structure.

The support structure also makes it possible to have a third or a third and fourth temperature control channel between two edge temperature control channels. This allows additional temperature control of the circuit board disposed on the upper side of the support structure.

The support structure allows the cell connectors, the support structure and the circuit board and the additional circuit board to be connected to form a module that can be mounted collectively. The cell connectors serve to establish an electrical connection between the individual energy storage cells and are therefore fixed, for example welded, to their pole contacts. By connecting the cell connectors, the support structure and the circuit board and the additional circuit board to form a collectively mountable module, a readymade or preassembled module can thus be created. By mounting the cell connectors on the energy storage cells, the support structure with the degassing channel, the temperature control channels and the circuit board and the additional circuit board can be mounted in a single operation. The cell contacting system can thus be advantageously kept in stock as a readymade or pre-assembled mounting module.

Furthermore, the at least one temperature control channel can have through openings disposed laterally to its longitudinal axis. These can serve to receive the cell connectors and/or overmolded temperature control geometries of the cell connectors and/or to fix them there.

The fact that the support structure is formed as a shaped part, preferably as an injection-molded part or as an extruded part, means that the required geometries can be easily implemented.

Preferably, the support structure is made of plastic. Plastic offers a high corrosion resistance, thermal insulation capability, and also electrical insulation capability with low weight. In addition, an electrically conductive fluid can be used in the temperature control channels. Aluminum or an aluminum alloy offer the advantage of increased mechanical resistance. Alternatively, the support part can be formed of aluminum or an aluminum alloy.

For example, the support structure is a profile structure, preferably a hollow profile structure.

The additional circuit board is preferably positioned in the degassing channel.

The degassing channel is preferably configured to be open on the first side of the support structure. The degassing channel of the support structure which is open on one side is thus located on the upper side of the energy storage cells, so that, when gases or vapors exit at the upper side of the energy storage cells, they can be conducted away along the degassing channel.

The support structure can advantageously have through-openings and/or fastening and/or centering devices and/or spacers for the circuit board. The fastening and/or centering devices serve, in particular, to fasten the circuit board in the correct position. Spacers can serve to ensure a certain spacing between the lower side of the circuit board and the support structure. Through-openings can serve to lead the contacting device between the circuit board and the additional circuit board through the support structure.

The support structure can further have a mounting recess in which the circuit board is positioned. This firstly influences the mechanical stability of the support structure. Secondly, the installation space at the top, i.e. in the direction away from the surface of the energy storage device, is reduced. Furthermore, the circuit board is located in a non-exposed position on the upper side of the support structure and is therefore more effectively protected against mechanical damage.

The sensor element can be a sensor element measuring an ambient parameter, preferably a temperature sensor element, a gas sensor element, a moisture sensor element or a pressure sensor element.

Furthermore, the sensor element can be fastened, preferably soldered, to the additional circuit board on the side facing away from the circuit board or on the side facing the circuit board. A temperature sensor element can advantageously be fastened to the additional circuit board on the side facing away from the circuit board. The sensor element can be contacted with the energy storage cell in this way. As an alternative or in addition, for example, a temperature sensor element, a gas sensor element, a moisture sensor element or a pressure sensor element can be fastened to the additional circuit board on the side facing the circuit board.

The sensor element, in particular a temperature sensor element, can expediently be disposed in the region of the spacers, i.e. adjacent to them.

The present invention further relates to an energy storage device, in particular an energy storage device for a vehicle, comprising a plurality of energy storage cells disposed in a row, wherein a circuit board arrangement according to the invention is provided on the energy storage device.

Other features which are considered as characteristic for the invention are set forth in the appended claims.

Although the invention is illustrated and described herein as embodied in a circuit board arrangement and an energy storage device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, perspective illustration of an exemplary embodiment of an energy storage device with a cell contacting system;

FIG. 2 is a perspective, longitudinal-sectional illustration of the exemplary embodiment of the energy storage device from FIG. 1 taken along the section line A-A;

FIG. 3 is a front view of the exemplary embodiment of the cell contacting system from FIG. 1;

FIG. 4a is a perspective illustration of the support structure of the cell contacting system from FIG. 1;

FIG. 4b is a perspective illustration of a further embodiment of a support structure;

FIG. 4c is a perspective illustration of a further embodiment of a support structure;

FIG. 5 is a perspective illustration of the cell contacting system from FIG. 1 as a mountable module;

FIG. 6a is a perspective illustration of the circuit board of the cell contacting system from FIG. 1 including the open-loop and closed-loop control electronics of the energy storage cells or the energy storage device, with temperature sensor arrangements fixed to the circuit board;

FIG. 6b is a perspective illustration of a further embodiment of a circuit board of the cell contacting system with temperature sensor arrangements fixed to the circuit board;

FIG. 7a is a perspective illustration of a temperature sensor arrangement of the cell contacting system from FIG. 1;

FIG. 7b is a sectional illustration of the temperature sensor arrangement from FIG. 7a;

FIG. 8a is a perspective illustration of a further embodiment of a temperature sensor arrangement for a cell contacting system;

FIG. 8b is a sectional illustration of the temperature sensor arrangement from FIG. 8a;

FIG. 9a is a detailed perspective illustration of the temperature sensor arrangement from FIG. 7a or 7b in the mounted state;

FIG. 9b is a detailed perspective view of the temperature sensor arrangement from FIG. 7b in the mounted state;

FIG. 10a is a perspective illustration of the circuit board arrangement formed of the circuit board and an additional circuit board of the cell contacting system from FIG. 1;

FIG. 10b is a perspective illustration of the circuit board arrangement formed of the circuit board and the additional circuit board of the cell contacting system from FIG. 1;

FIG. 11a is plan view of the cell contacting system from FIG. 1 with the support structure omitted;

FIG. 11b is a perspective illustration of the cell contacting system from FIG. 1 with the support structure omitted;

FIG. 12a is a partial perspective illustration of the circuit board arrangement from FIG. 1 in the region of the spacers;

FIG. 12b is a partial perspective illustration of the circuit board arrangement from FIG. 1 in the region of the connection between the circuit board and the additional circuit board;

FIG. 12c is a partial perspective illustration of an alternative embodiment of the circuit board arrangement in the region of the connection between the circuit board and the additional circuit board;

FIG. 13a is a detailed perspective illustration of a cell connector from FIG. 1;

FIG. 13b is a detailed perspective illustration of a cell connector on the connection side from FIG. 1;

FIG. 14a is a perspective illustration of a further embodiment of a temperature control structure of a cell connector;

FIG. 14b is a perspective illustration of a further embodiment of a temperature control structure of a cell connector;

FIG. 14c is a perspective illustration of a further embodiment of a temperature control structure of a cell connector;

FIG. 14d is a perspective illustration of a further embodiment of a temperature control structure of a cell connector;

FIG. 15a is a perspective illustration of a further embodiment of a cell connector;

FIG. 15b is a side view of the cell connector according to FIG. 15a;

FIG. 16a is a perspective illustration of a further embodiment of a cell connector;

FIG. 16b is a side sectional view of the cell connector according to FIG. 16a;

FIG. 17a is a perspective illustration of a further embodiment of a cell connector; and

FIG. 17b is a perspective illustration of a further embodiment of a cell connector without a temperature control structure.

### DETAILED DESCRIPTION OF THE INVENTION

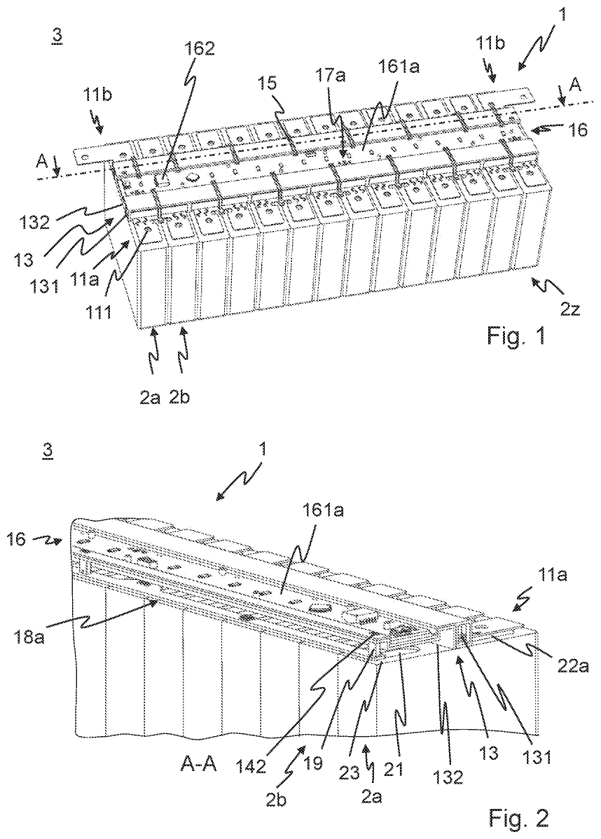

Referring now to the figures of the drawings in detail and first, particularly, to FIG. 1 thereof, it is seen that reference numeral 3 designates an energy storage device in its entirety. This is in particular a battery, for example for an electric vehicle with an electric drive. The energy storage device 3 has a plurality of energy storage cells 2a, 2b, 2z connected in series. Reference numeral 1 denotes an example of a cell contacting system which is intended for electrically connecting the individual energy storage cells 2a, 2b, 2z to one another.

The energy storage cells 2a, 2b, 2z each have two pole contacts 22a, 22b (of which only one pole contact 22a can be seen in FIG. 2), specifically one pole contact 22a for an anode and one pole contact 22b for a cathode. The pole contacts 22a, 22b can have a substantially flat surface or can be formed as small plates.

The cell contacting system 1 further includes a support structure 13 as well as cell connectors 11a, 11b attached to the support structure 13, which serve to electrically contact and connect the individual energy storage cells 2a, 2b, 2z. Furthermore, open loop and/or closed loop control electronics 16 are positioned on the support structure 13 and are electrically connected to the cell connectors 11a, 11b by connection elements 15. The open loop and/or closed loop control electronics 16 include a circuit board 161a which is equipped with corresponding electronic components 162 and which is connected to the support structure 13.

Since the cell connectors 11a, 11b are connected to the cell contacting system 1, the complete cell contacting system 1 can be attached to the energy storage cells 2a, 2b, 2z of the energy storage device 3 by the cell connectors 11a, 11b. For this purpose, the cell connectors 11a, 11b can be welded to the pole contacts 22a, 22b, for example. The cell contacting system 1 can thus be kept in stock as an assembled module and can be mounted on the energy storage cells 2a, 2b, 2z as a unit in a single process step within an automated production line.

The cell contacting system 1 includes temperature control channels 131 and a degassing channel 132, each described in greater detail below, which are integrated into the support structure 13 in accordance with the invention. The temperature control channels 131 serve to conduct a gaseous or liquid fluid (not shown in the figures) through the energy storage device 3 in order to control the temperature of the latter. The degassing channel 132 serves to remove, in a controlled manner, gases released in the event of a so called “thermal runaway” of the energy storage device 3. A degassing opening 21 can be seen in FIG. 2. It opens out into the degassing channel 132. The degassing opening 21 can, for example, be formed as a predetermined breaking point, so that in the event of a thermal runaway the gases produced inside the energy storage cells 2a, 2b, 2z can escape at this point.

In the exemplary embodiment, fourteen energy storage cells 2a, 2b, 2z are shown, which are electrically connected to each other in a series circuit by the cell contacting system 1. For this purpose, the energy storage cells 2a, 2b, 2z are each disposed rotated relative to one another, so that the pole contact 22a of the anode of the energy storage cell 2a is opposite the pole contact 22b of the cathode of the adjacent energy storage cell 2b, or the pole contact 22b of the cathode of the energy storage cell 2b is opposite the pole contact 22a of the anode of the adjacent energy storage cell 2a. The pole contact 22b of the cathode of the first energy storage cell 2a is connected to the terminal cell connector 11b. The pole contact 22a of the anode of the first energy storage cell 2a is connected by the cell connector 11a to the pole contact 22b of the cathode of the adjacent, second energy storage cell 2b. The pole contact 22a of the anode of the second energy storage cell 2b is in turn connected to the pole contact 22b of the cathode of the third energy storage cell by a cell connector 11a, and so on. The pole contact 22a of the anode of the last energy storage cell 2z is connected to the cell connector 11b. The cell connectors 11b are intended to electrically connect the energy storage device 3 to an electrical consumer, not shown, for example the electric motor of an electric vehicle. The two cell connectors 11b thus form the energy storage device connections, i.e. the cathode and anode of the entire energy storage device 3.

In alternative embodiments of an energy storage device 3, a different number of energy storage cells can also be provided and/or the energy storage cells can be connected in parallel by the cell contacting system 1. For this purpose, the cell connectors 11a, 11b can, for example, connect the electrical connections 22a of the anodes of two or more energy storage cells or the electrical connections 22b of the cathodes of two or more energy storage cells. The energy storage cells can also be disposed in a row in the same orientation, i.e. not rotated, so that the electrical connections of the cathodes of the energy storage cells of the energy storage device 3 are disposed along a first line and the electrical connections of the anodes of the energy storage cells are disposed along a second line running parallel to the first line.

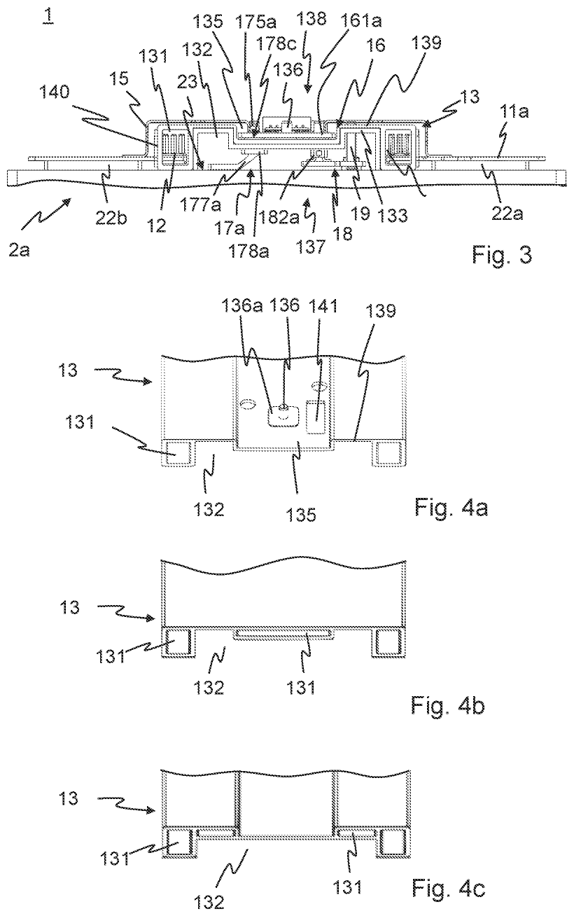

FIG. 3 shows a front view of the cell contacting system 1. The support structure 13 has a first side 137 facing the energy storage device 3 or the energy storage cells 2a, 2b, 2z, which serves as the mounting side for mounting on the energy storage device 3 or the energy storage cells 2a, 2b, 2z (not shown in FIG. 3), and a second side 138 facing away from the energy storage device 3 or the energy storage cells 2a, 2b, 2z. Furthermore, the support structure 1 has two lateral temperature control channels 131 located in the region of the cell connectors. The temperature control channels 131 and the degassing channel 132 are molded into the support structure 1 in accordance with the invention.

The degassing channel 132 is formed by the lateral temperature control channels 131, which are opposite each other, and by a wall 139, which runs between the temperature control channels 131. The degassing channel 132 is open on the first side 137 of the support structure 13 to the energy storage cells 2a, 2b, 2z. This allows gases to pass from the degassing openings 21 of the energy storage cells 2a, 2b, 2z into the degassing channel 132 in the assembled state of the cell contacting system 1 and to be discharged from there in a controlled manner. This increases the protection of vehicle occupants.

As can be seen from FIG. 4a, the support structure 13 is embodied as a shaped part, in particular as an injection-molded part or extruded part, preferably in particular as an injection-molded plastics part or an extruded plastics part. The support structure 13 can be formed as a profile structure, preferably as a hollow profile structure. In this way, a cell contacting system 1 with a comparatively low weight can be created.

The support structure 13 is provided with a protective layer 133 (see FIG. 3) in the region of the first side 137, in particular for protecting against heat and/or abrasive media and/or chemical influences (for example by acids). The protective layer 133 may be formed of a heat resistant and/or acid resistant material. The protective layer 133 may be either an applied coating (for example a liquid, curable coating, for example a lacquer with the addition of ceramic particles, a foamed and cured coating, or a powder coating) or a layer applied to the wall (for example mica sheets, ceramic fiber mats, glass fiber mats or carbon mats, or cork sheets) or a combination thereof. The protective layer may also be provided additionally under the temperature control channels 131a, 131b if required (not shown in the figures).

The temperature control channels 131 are each formed by a hollow chamber. As can be seen in FIG. 3, the temperature control channels 131 have lateral through openings 140, into which cell connectors 11a, 11b overmolded with a cooling structure 12 are inserted and fastened. The cooling structure 12 can, for example, be adhesively bonded and/or welded to the support structure 1. In this way, the through opening 140 is tightly sealed. The cooling structure 12 of the cell connectors 11a, 11b is surrounded by the fluid for temperature control in the temperature control channels 131 and are in thermal contact with the fluid.

Furthermore, the support structure 13 has a mounting recess 135 on the second side 138 opposite the degassing channel 132. This is formed by an offset of the wall 139. The mounting recess 135 serves to position the open loop and/or closed loop control electronics 16 in a particularly space saving manner. Fastening and/or centering device 136 can be provided at the mounting base of the mounting recess 139 for fastening and/or centering the circuit board of the open loop and/or closed loop control electronics 16. Spacers 136a may also be provided, which cause the underside of the open loop and/or closed loop control electronics 16 or circuit board 161a thereof to be spaced apart from the mounting base of the mounting recess 139. The mounting recess 135 allows a flat structure of the cell contacting system 1. The offset of the wall 139 forming the mounting recess 135 also serves to increase the mechanical stability of the support structure 13. The offset acts in this case as a bead, i.e. a channel shaped stiffening device, which increases the second moment of area of the support structure 13. The support structure 13 can thus better withstand, for example, an increase in pressure in the degassing channel 132 occurring during degassing of the energy storage cells 2a, 2b, 2z. Furthermore, the wall 139 has through openings 141 for temperature sensor arrangements 17a, 17b and/or for contacting a sensor circuit board 18a, 18b.

The circuit board 161a has, for example, holes through which the circuit board 161a is fitted on the fastening and/or centering device 136, which in the exemplary embodiment are in the form of “domes.” The ends of the domes can then be upset to form mushroom heads, thereby fastening the circuit board 161a to the support structure 13.

If required, more than two temperature control channels 131 may also be formed in the support structure 13. For example, as shown in FIG. 4b, an additional temperature control channel 131 can be located in the middle on the underside of the wall 139, whereby the wall 139 between the two outer temperature control channels 131 and thus a circuit board located on the upper side can be additionally temperature controlled.

According to the embodiment shown in FIG. 4c, a second temperature control channel 131 is provided in each side region.

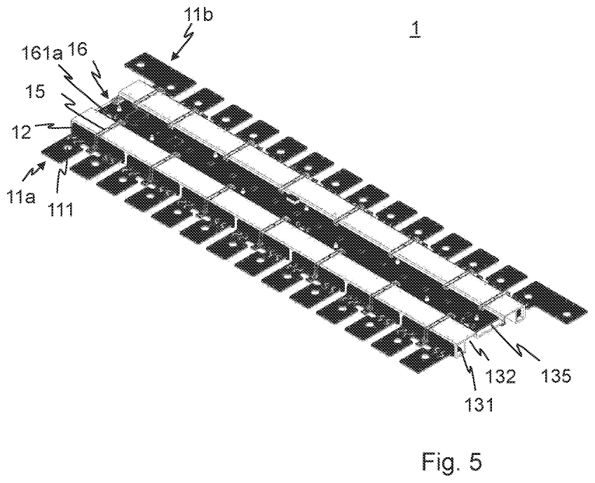

FIG. 5 shows the cell contacting system 1 according to the invention as a pre-assembled module including the cell connectors 11a, 11b, the temperature control channels 131, the degassing channel 132 and the open loop and/or closed loop control electronics 16. The cell contacting system 1 simplifies the manufacture of energy storage devices 3 considerably in that only the cell connectors can be mounted on the energy storage cells, for example by welding.

Alternatively, the cell connectors can also be screwed or soldered to the energy storage cells.

Through openings 111, for example through holes, can be provided on the cell connectors 11a, 11b. These can serve as inspection openings. Furthermore, if required, measuring lines can also be attached, through these through openings 111, to threaded holes located beneath the through openings 111 on the pole contacts 22a, 22b. In this way, for example, the contacting of the cell connectors 11a, 11b to the pole contacts 22a, 22b can be checked.

Alternatively, the cell connectors 11a, 11b could also be connected, for example screwed, to the pole contacts 22a, 22b by the through openings 111 if required.

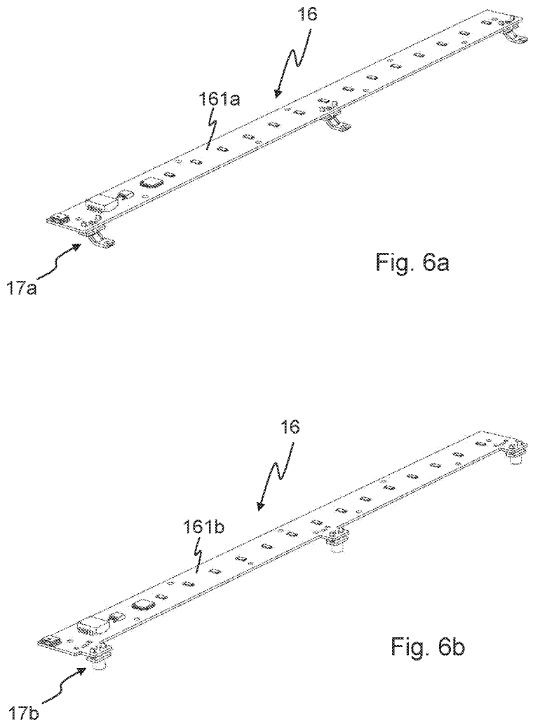

FIGS. 6a and 6b show two exemplary embodiments of temperature sensor arrangements 17a, 17b for detecting the temperature on an upper side 23, not shown, of an energy storage cell 2a, 2b, 2z. In the exemplary embodiments, the temperature sensor arrangement 17a is mounted on the circuit board 161a and the temperature sensor arrangement 17b is mounted on the circuit board 161b by a snap connection in each case. The circuit board 161b can also be provided for temperature sensor arrangements 17a.

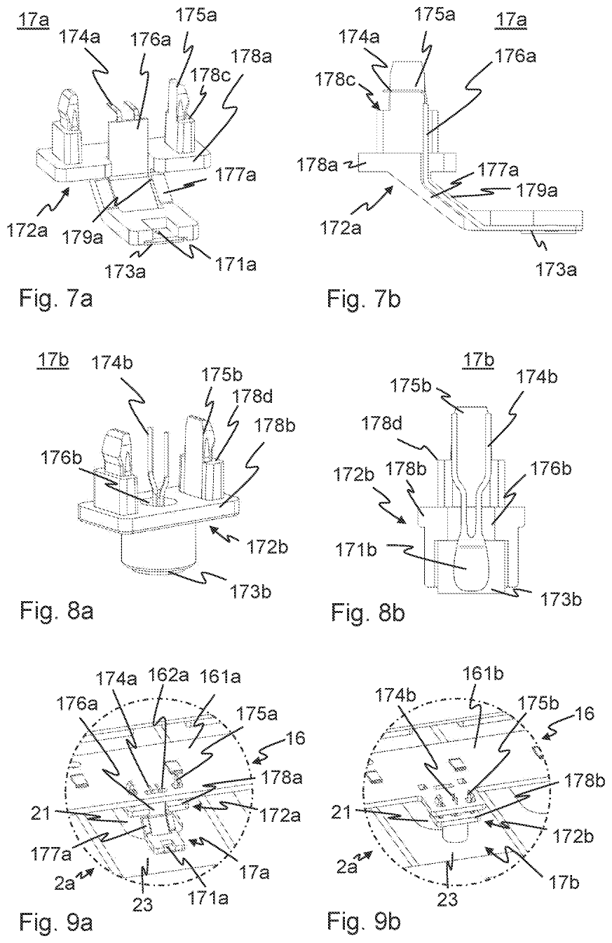

FIGS. 7a and 7b show a perspective illustration and a sectional illustration of a first exemplary embodiment of the temperature sensor arrangement 17a.

The temperature sensor arrangement 17a includes a flexible sensor circuit board 176a having a sensor element 171a integrated on the sensor circuit board 176a and a shaped housing element 172a for mounting on the circuit board 161a, 161b from FIGS. 6a, 6b.

The shaped housing element 172a includes a guide channel 179a for the flexible sensor circuit board 176a and thus serves to position and hold the sensor element 171a. Furthermore, the shaped housing element 172a has a base 178a with a connection device 175a and an elastically deflectable spring arm 177a. The connection device 175a is configured as a snap connection with two resilient detent arms. They are used to connect to the circuit board 161a from FIG. 6a. Steps 178c are also provided on the connection device 175a and serve as a contact point on the underside of the circuit board 161a.

The sensor circuit board 176a has electrical connections 174a which are electrically connected to the sensor element 171a by conductor tracks that are not shown.

In addition, an elastic, thermally conductive contact element 173a is provided on the underside of the temperature sensor arrangement 17a in the region of the sensor element 171a in order to avoid gap formation and to transfer the temperature of the energy storage cells to be detected to the sensor element 171a.

FIG. 9a shows the temperature sensor arrangement 17a of FIGS. 7a and 7b in the assembled state without the support structure 13. The detent arms engage through recesses provided on the circuit board 161a and thus establish a mechanical connection to the circuit board 161a. The spring arm presses the sensor element 171a onto the upper side 23 of the energy storage cell 2a. The electrical connections 174a extend through the circuit board 161a through a slot shaped recess 162a and are connected to the circuit board 161a, for example soldered by solder pads.

When mounting the temperature sensor arrangement 17a, the shaped housing element 172a can first be connected to the sensor circuit board 161a. The sensor circuit board 176a can then be inserted from the side opposite the shaped housing element 172a through the slot shaped recess 162a of the circuit board 161a into the guide channel 179a of the shaped housing element 172a. After the sensor circuit board 176a is positioned in the guide channel 179a, the electrical connections 174a of the sensor circuit board 176a can be connected to the circuit board 161a. This facilitates handling. In addition, the assembly can be automated as a result.

As can be seen from FIG. 3, the temperature sensor arrangement 17a extends through the through opening 141 (cf. FIG. 4a) of the support structure 13 and can thus be positioned in the degassing channel 132. The support structure 13 causes a thermal separation of the circuit board 161a from the sensor element 171a. As a result, the circuit board 161a remains intact even in the event of thermal destruction of the temperature sensor arrangement 17a, and the defect in the temperature sensor arrangement 17a, 17b can still be detected by the open loop and/or closed loop control electronics 16. The steps 178c lie against the underside of the circuit board 161a.

The base 178a is provided to cover or close the through opening 141 of the support structure on the first side 137 thereof. A flow of gases through the through opening 141 is thus prevented or at least reduced.

FIGS. 8a and 8b show a perspective view and a sectional view of a further embodiment of a temperature sensor arrangement 17b.

The temperature sensor arrangement 17b includes a sensor element 171b and a shaped housing element 172b. The shaped housing element 172b includes a base 178b with a connection device 175b and a step 178d, which have a corresponding structure and the same function as the base 178a, the connection device 175a and the step 178c of the temperature sensor arrangement 17a according to FIGS. 7a and 7b.

In this embodiment, the shaped housing element 172b of the temperature sensor arrangement 17b has a chamber 176b for positioning the sensor element 171b. The chamber 176b is open on the side facing the circuit board 161a, 161b, 161c. This allows the sensor element 171b to be pushed into the chamber 176b.

The sensor element 171b may be a wired electronic component for through hole technology (THT) with two electrical connections 174b.

A contact element 173b, which at least partially encloses the sensor element 171a, is located on the side of the shaped housing element 172b facing away from the electrical connections 174b. The contact element 173b is formed of an elastic, thermally conductive material. Further, the contact element 173b is partially enclosed by the chamber 176b and abuts a shoulder in the chamber 176b.

FIG. 9b shows the temperature sensor arrangement 17b from FIGS. 8a and 8b in the assembled state without the support structure 13.

The temperature sensor arrangement 17b is mechanically connected to the circuit board 161b by snap connection by the connection device 175b.

In order to connect the electrical connections 174b, the circuit board 161b can have contact holes with contact rivets, for example. The electrical connections 174b can be inserted through these holes and soldered to the circuit board 162b from the side opposite the sensor element 171b.

The contact element 173b, which is concealed by the shaped housing element 172b in FIG. 9b, is compacted or compressed. This allows the sensor element 171b to be installed pressing with a certain contact pressure onto the upper side 23 of the energy storage cell 2a.

The temperature sensor arrangement 17b may be mounted on the circuit board 161b as an assembled module.

By pressing the temperature sensor arrangements 17a, 17b, a good thermal contact is ensured. In addition, it is possible to compensate for manufacturing tolerances, thermal expansions or relative movements of the components.

One of the two temperature sensor arrangements 17a, 17b or a combination of both of them may be provided in the cell contacting system 1.

A circuit board can be a printed circuit board, i.e. a printed circuit for carrying electronic components.

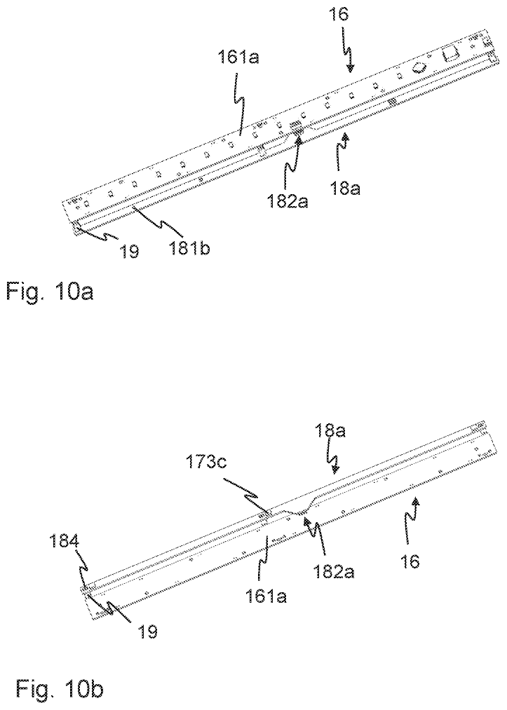

FIGS. 10a and 10b show a circuit board arrangement of the cell contacting system 1 in the form of the circuit board 161a with an additional circuit board 18a on which sensor elements 181b and, in FIG. 10b, sensor elements 181a concealed by contact elements 173c, such as temperature sensor elements, gas sensor elements, moisture sensor elements or pressure sensor elements, are located. FIGS. 2 and 3 show the positioning of the circuit board arrangement according to FIGS. 10a and 10b on the energy storage cells 2a, 2b, 2z of the energy storage device 3.

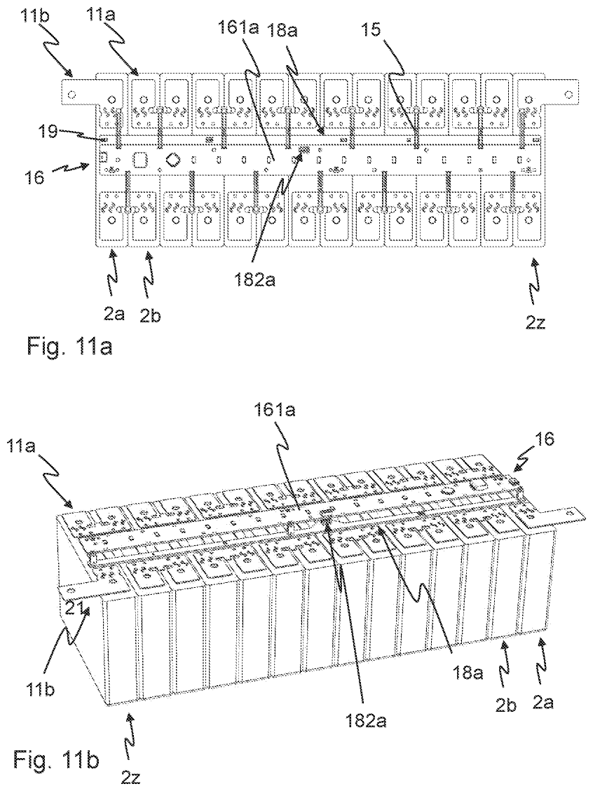

FIGS. 11a and 11b show the positioning of the circuit board arrangement according to FIGS. 10a and 10b on the energy storage cells 2a, 2b, 2z of an energy storage device 3, with omission of the support structure 13 for illustrative purposes. The circuit board arrangement can be used to position sensors for different parameters, for example for temperature, for gas, for pressure and/or for moisture, along the surface of the energy storage device 3.

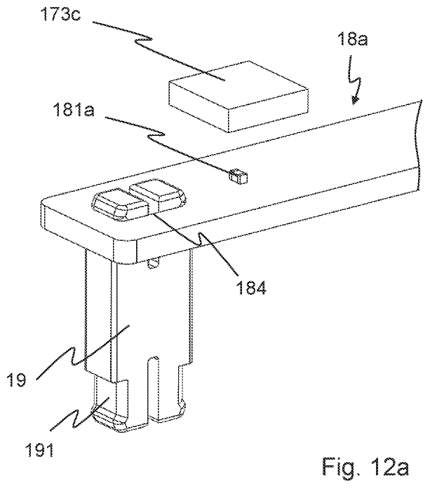

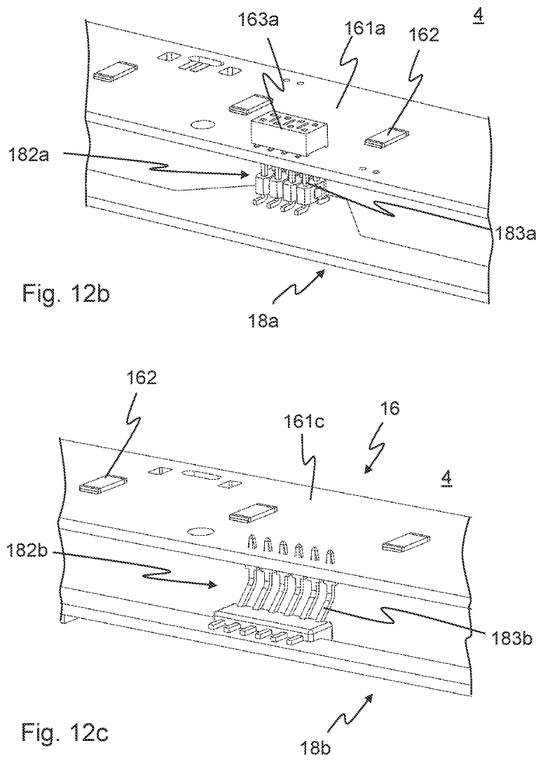

FIG. 12a shows an enlarged detail of an additional circuit board 18a according to FIGS. 10a and 10b in the region of the spacer 19.

FIG. 12b shows an enlarged illustration of the contacting device 182a between circuit board 161a and additional circuit board 18a.

FIG. 12c shows an alternative embodiment of a circuit board 161c and an additional circuit board 18b with alternative contacting device 182b.

According to FIGS. 10a and 10b, the additional circuit board 18a and the circuit board 161a are spaced apart, vertically offset from each other and electrically connected to each other by a contacting device 182a. In the assembled state of the cell contacting system 1, the contacting device 182a extend through a through opening 141 of the support structure 13 (see FIG. 3). In an advantageous manner, this allows the additional circuit board 18a to be positioned on the side 137 of the support structure 13 facing the energy storage device within the degassing channel 132. This results in a thermal separation of the additional circuit board 18a from the circuit board 161a through the wall 139 and/or the protective layer 133 of the support structure 13.

The additional circuit board 18a in FIGS. 10a, 10b is plate shaped and mechanically connected to the support structure 13 by spacers 19. As shown in FIG. 12a, the spacers 19 each have a connection device 191 on the side facing the additional circuit board 18a and on the side facing the support structure 13. The connection elements 191 may be in the form of a snap connection with two detent arms. The detent arms are resilient elements that can each engage through the additional circuit board 18a and the support structure 13 to establish a mechanical connection to the additional circuit board 18a and the support structure 13. For this purpose, the additional circuit board 18a can have recesses 184 and the support structure 13 can have recesses 142 (see FIG. 2) in which the connection elements 191 can engage.

Sensor elements 181a, 181b are provided on the additional circuit board 18a and are electrically connected to the circuit board 161a by conductor tracks, not shown, and by the contacting device 182a, 181b. The sensor elements 181a, 181b can be SMD components, for example, which are soldered to the additional circuit board 18a at solder pads.

According to FIG. 10a, the sensor element 181b is located on the side of the additional circuit board 18a facing the circuit board 161a. The sensor element 181b can be, for example, a sensor element measuring an ambient parameter, for example a temperature sensor element, a gas sensor element, a moisture sensor element or a pressure sensor element. The sensor element 181b is not in direct contact with an energy storage cell when the cell contacting system 1 is assembled. As a result, the sensor element 181b can be used to measure, for example, a gas temperature, a gas composition, a moisture or a pressure in the degassing channel 132. The sensor element 181b can also be an electronic component that can detect a plurality of ambient parameters.

As shown in FIG. 12a, the sensor element 181a is located on the side of the additional circuit board 18a facing away from the circuit board or facing the energy storage cells. The sensor element 181a can, for example, be a temperature sensor element, for example a Pt 100 resistor configured as an SMD component. A contact element 173c is located on the sensor element 181a and is in contact with the sensor element 181a (shown enlarged and spaced apart in FIG. 12a). The contact element 173c is formed of a thermally conductive, elastic material. When mounting the cell contacting system 1 on the energy storage cells of the energy storage device 3, the contact element 173c can be compacted or compressed. As a result, the sensor element 181a can be pressed onto the upper side 23 of the energy storage cell with a certain contact force. For this purpose, the sensor elements 181a can advantageously be located in the region of the spacers 19. By pressing the sensor element 181a, thermal contact is ensured. In addition, it is possible to compensate for manufacturing tolerances, thermal expansions or relative movements of the components.

According to FIGS. 12b and 12c, the contacting devices 182a, 182b are protruding conductor bars 183a, 183b, which can be soldered, for example, to solder pads on the additional circuit board 18a, 18b.

According to FIG. 12b, the circuit board 161a has through openings for the contacting device 182a and a contacting strip 163a. The contacting strip 163a can be soldered to the circuit board 161a. The conductor bars 183a can be plugged into the contacting strip 163a. The contacting strip 163a can have spring contacts for this purpose, for example.

According to FIG. 12c, the circuit board 161c has press fit through openings for the contacting device 182b. The conductor bars 183b can be pressed into the press fit through openings.

The additional circuit board 18b has a different configuration in the region of the contacting device 182b as compared to the additional circuit board 18a.

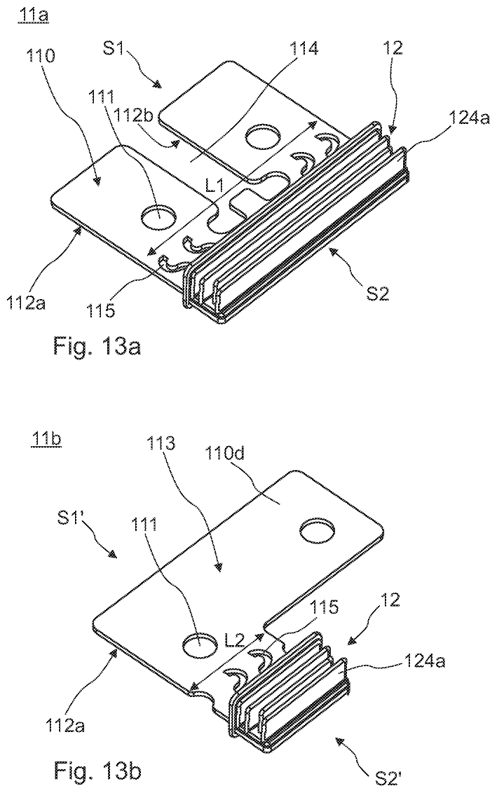

FIGS. 13a and 13b show cell connectors 11a, 11b for electrically contacting the pole contacts 22a, 22b of the energy storage cells 2a, 2a, 2z. In the exemplary embodiment, two terminal cell connectors 11b and thirteen cell connectors 11a are shown.

The cell connectors 11a are intended to electrically connect a pole contact 22a of one energy storage cell, for example 2a, to a pole contact 22b of an adjacent energy storage cell, for example 2b. For this purpose, the cell connectors 11a have a main body 110 with a first contact face 112a and a second contact face 112b, which are each connected, for example welded, to a pole contact 22a, 22b.

The two cell connectors 11b are intended to provide, at the first energy storage cell 2a and the last energy storage cell 2z, a contacting device to an electrical consumer, not shown, for example an electric motor of an electric vehicle, or to an adjacent energy storage device. The cell connectors 11b have a main body 113 with a contact face 112a which is connected, for example welded, to the pole contact 22b of the cathode of the first energy storage cell 2a or the pole contact 22a of the anode of the last energy storage cell 2z. Furthermore, the main body 113 has a current tap 110d. The current taps 110d of the two cell connectors 11b thus form the connections of the anode and cathode of the energy storage device 3.

The main body 110, 113 of the cell connector 11a, 11b is formed of an electrically conductive flat material with preferably a constant layer thickness, for example a sheet metal. The main body 110, 113 has a first side S1, S1′ and a second side S2, S2′ and is overmolded in each case in the region of the second side S2, S2′ in a partial region 110a with a temperature control structure 12 which increases the surface area of the cell connector 11a, 11b. The temperature control structure 12 has, for example, a plurality of temperature control ribs 124a running parallel to one another.

The temperature control structure 12 is preferably a thermally conductive, electrically insulating material, in particular plastic.

In the cell connector 11a, the temperature control structure 12 extends along the entire length L1 of the first side S1. In the cell connector 11b, the temperature control structure 12 extends only along the length L2 of the first side S1′ in the region of the contact face 112a.

A recess 114 may be provided between the contact faces 112a, 112b of the cell connector 11a. On the one hand, this recess shifts the flow of current and the resultant heat into the partial region 110a overmolded by the temperature control structure 12. On the other hand, the main body 110 thus has a higher elasticity. It is thus possible to better compensate for thermal expansions or movements of the adjacent energy storage cells 2a, 2b, 2z relative to each other.

Furthermore, the main bodies 110, 113 of the cell connectors 11a, 11b can have recesses 115, for example in the form of crescent shaped through openings. These also increase the elasticity of the main bodies 110, 113.

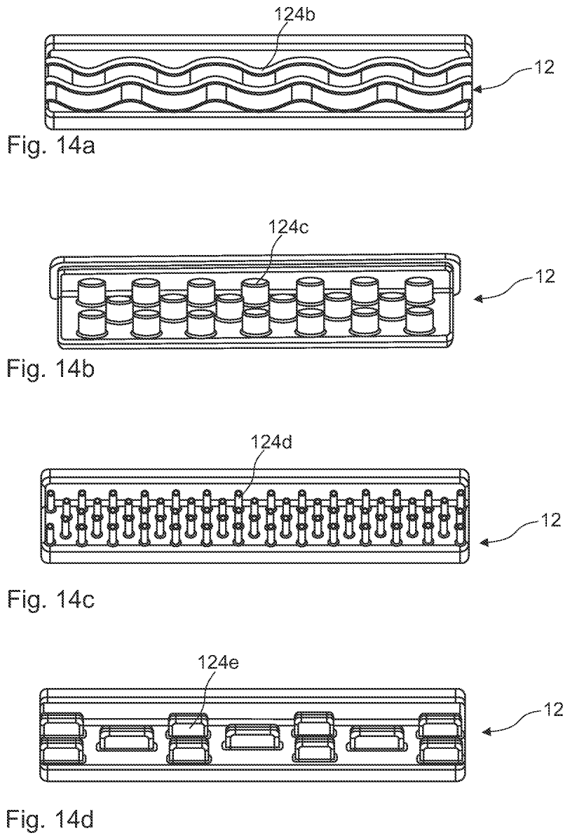

FIGS. 14a to 14d show various embodiments of the temperature control structure 12. Temperature control wave structures 124b, temperature control nubs 124c, temperature control pins 124d, or temperature control bars 124e may be provided as the temperature control structure.

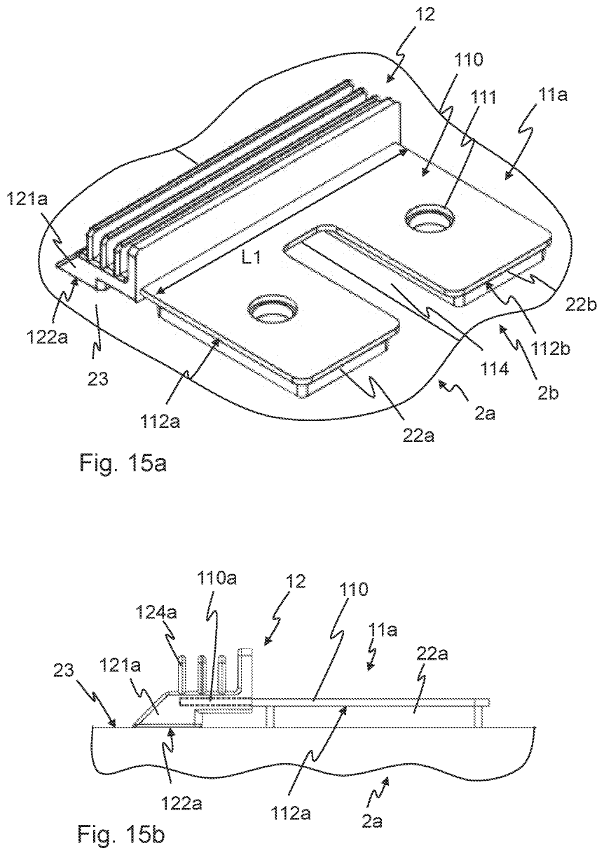

FIGS. 15a, 15b, 16a, 16b, 17a and 17b show alternative embodiments of cell connectors 11a, in which an additional contact element 121a, 121b, 121c is provided which is in direct contact with the upper side 23 of the energy storage cell by a contact face 122a, 122b, 122c. This allows for temperature control of the energy storage cells 2a, 2b, 2z.

The contact element 121a of the temperature control structure 12 from FIGS. 15a and 15b is injection molded in this case around the end region of the main body 110 in such a way that its contact face 122a rests on the surface of the energy storage cells 2a, 2b or bridges the height of the pole contacts 22a, 22b, cf. FIGS. 15a, 15b.

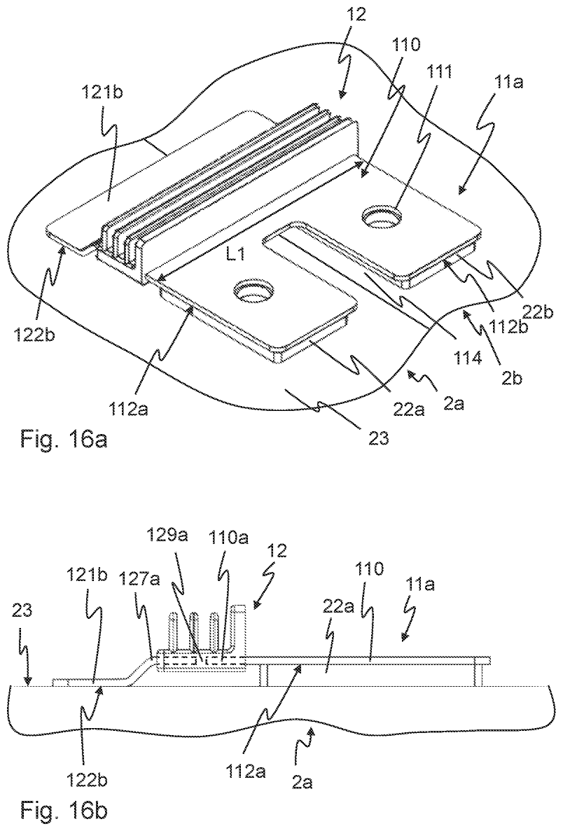

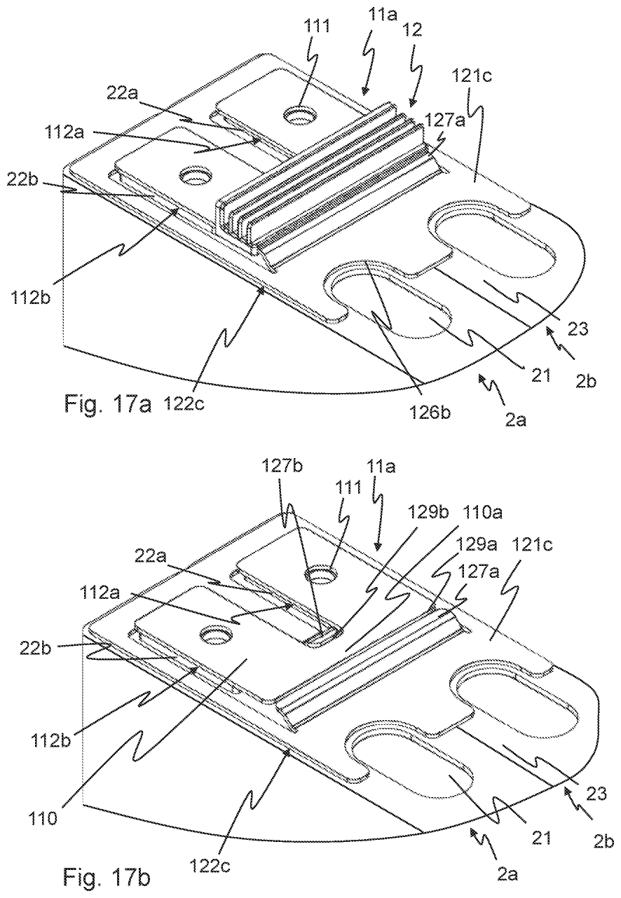

FIGS. 16a and 16b and FIGS. 17a and 17b show two further alternative embodiments of cell connectors 11a with a contact element 121b, 121c, for example a contact plate.

According to FIGS. 16a and 16b, the contact element 121b is overmolded by the temperature control structure 12 and has an offset 127a. The offset 127a may have substantially the same height as the pole contacts 22a, 22b with respect to the surface 23. This allows the main body 110 and the contact element 121b to be connected to each other, for example, in one plane, with the result that the contact element 121b rests directly on the upper side of the energy storage cells. A gap 129a is provided between the main body 110 and the contact element 121b so that the main body 110 and the contact element 121b are not in direct contact with each other. The main body 110 and the contact element 121b are connected to each other by the temperature control structure 12. The main body 110 and the contact element 121b, 121c can thus be electrically insulated from each other by an electrically non conductive temperature control structure 12. The contact element 121b can be made of the same material as the main body 110.

The variant of FIGS. 17a and 17b has an additional offset 127b between the two contact faces 112a, 112b. The contact element 121c extends as far as the degassing openings 21 and surrounds the pole contacts 22a, 22b of the energy storage cells 2a, 2b. The additional offset 127b can additionally increase the heat conduction between the contact element 121c and the temperature control structure 12 as well as the mechanical stability of the cell connector 11a.

The offset 127a, 127b can be created, for example, by two folds of a plate shaped raw material, for example a metal sheet, as can be seen in FIG. 17b, in which the temperature control structure has been omitted for illustrative purposes.

The main body 110 and the contact elements 121b, 121c can advantageously be made, for example cut or punched, from a common plate shaped blank.

Corresponding contact elements can also be provided for the terminal cell connectors 11b. The geometry of the contact element for a cell connector 11b can be easily adapted to the geometry of the cell connector 11b.

The cell connectors 11a, 11b can have an interface to a temperature control channel 131 and can be connected to the latter, for example welded or adhesively bonded, preferably in the region of the temperature control structure 12. For this purpose, the through openings 140 of the support structure 13 can be disposed laterally in the direction of the pole contacts and/or in the direction of the degassing channel and/or in the direction of the battery storage cells.

The temperature control structure 12 of the cell connectors can close the through openings 140 of the support structure 13. In addition, the temperature control structure 12 may insulate the base element 110, 113 and/or the contact element 121b, 121c with respect to a temperature control fluid located in the temperature control channel 131. Thus, for example, a fluid formed of an electrically conductive fluid may be provided. The temperature control structure 12 may likewise insulate the base element 110, 113 and/or the contact element 121b, 121c with respect to the support structure 13. Alternatively, the support element in this variant could, for example, be formed of a metal, for example aluminum or an aluminum alloy.

Alternatively, the embodiments of the cell connectors 11a, 11b can also be used without a temperature control channel 131. In this case, the ambient air can be used for temperature control, for example.

The following is a summary list of reference numerals and the corresponding structure used in the above description of the invention:

### LIST OF REFERENCE SIGNS

1 cell contacting system
2a first energy storage cell
2b second energy storage cell
2z last energy storage cell
3 energy storage device
4a circuit board arrangement
4b circuit board arrangement
11a cell connector
11b cell connector
111 through opening
110 main body
113 main body
110a partial region
110d current tap
112a contact face
112b contact face
12 temperature control structure
121a contact element
121b contact element
121c contact element
122a contact face
122b contact face
122c contact face
124a temperature control ribs
124b temperature control wave structure
124c temperature control nubs
124d temperature control pins
124e temperature control bars
127a offset
127b offset
129a gap
129b gap
13 support structure
131 temperature control channel
132 degassing channel
133 protective layer
135 mounting recess
136 fastening and/or centering device
136a spacer
137 first side
138 second side
139 wall
140 through opening
141 through opening
142 recess
15 connection elements
16 open-loop and/or closed-loop control electronics
161a circuit board
161b circuit board
161c circuit board
162 electronic components
162a recess
163a contacting strip
17a temperature sensor arrangement
17b temperature sensor arrangement
171a temperature sensor element
171b temperature sensor element
172a shaped housing element
172b shaped housing element
173a contact element
173b contact element
173c contact element
174a connections
174b connections
175a connection device
175b connection device
176a circuit board
177a spring arm
178a base
178b base
178c step
178d step
179a guide channel
18a additional circuit board
18b additional circuit board
181a sensor element
181b sensor element
182a contacting device
182b contacting device
183a conductor bars
183b conductor bars
184 recesses
19 spacer
191 connection device
21 degassing opening
22a pole contact
22b pole contact
23 upper side

1. A circuit board arrangement for a cell contacting system for contacting energy storage cells of an energy storage device or an energy storage device for a vehicle, the circuit board arrangement comprising:
a circuit board;
at least one of open-loop or closed-loop control electronics disposed on said circuit board for at least one of open-loop or closed-loop control of at least one of the energy storage device or a respective energy storage cell;
an additional circuit board including at least one sensor element, said additional circuit board being spaced apart from said circuit board and defining a spacing between said additional circuit board and said circuit board; and
a contacting device electrically connecting said circuit board and said additional circuit board to each other, said contacting device bridging said spacing between said additional circuit board and said circuit board.

2. The circuit board arrangement according to claim 1, wherein said circuit board and said additional circuit board have main surfaces being vertically offset.

3. The circuit board arrangement according to claim 1, wherein said additional circuit board is plate-shaped.

4. The circuit board arrangement according to claim 1, wherein said at least one sensor element has a thermally conductive or thermally conductive elastic contact element permitting said at least one sensor element to be contacted with a surface of an energy storage cell.

5. The circuit board arrangement according to claim 1, wherein said additional circuit board and said circuit board are elongate and run adjacent to each other.

6. The circuit board arrangement according to claim 1, which further comprises:
a support structure configured to be mounted on the energy storage device or on the energy storage cells;
the support structure having a first side facing the energy storage device in an installed state and a second side facing away from the energy storage device in the installed state;
said circuit board being fastened to the second side of the support structure; and
said additional circuit board being positioned on the first side of the support structure.

7. The circuit board arrangement according to claim 6, which further comprises spacers provided between the first side of the support structure and said additional circuit board.

8. The circuit board arrangement according to claim 7, wherein said spacers include:
at least one connection element or snap connection element disposed on the side facing the support structure or the side facing said additional circuit board, or
two connection elements or two snap connection elements disposed on the side facing the support structure and on the side facing said additional circuit board.

9. The circuit board arrangement according to claim 1, wherein said contacting device includes conductor bars protruding from said additional circuit board and passing through said circuit board.

10. The circuit board arrangement according to claim 9, wherein said conductor bars pass through said circuit board in a region of a through-opening in said circuit board.

11. The circuit board arrangement according to claim 10, wherein said conductor bars pass through said circuit board as a press-fit arrangement.

12. The circuit board arrangement according to claim 9, wherein said conductor bars are contacted on a side of said circuit board facing away from said additional circuit board.

13. The circuit board arrangement according to claim 12, which further comprises a plug-mountable contacting strip providing contact between said conductor bars and the side of said circuit board facing away from said additional circuit board.

14. The circuit board arrangement according to claim 6, which further comprises cell connectors for electrically connecting the energy storage cells to form a unit to be mounted collectively, said support structure being connected to said cell connectors.

15. The circuit board arrangement according to claim 6, wherein said support structure has at least one of a degassing channel integrated into said support structure or at least one temperature control channel integrated into said support structure.

16. The circuit board arrangement according to claim 15, wherein said additional circuit board is positioned in said degassing channel.

17. The circuit board arrangement according to claim 15, wherein said degassing channel is open on said first side of said support structure.

18. The circuit board arrangement according to claim 6, wherein said support structure has at least one of through-openings or a fastening or centering device or spacers for said circuit board.

19. The circuit board arrangement according to claim 6, wherein said support structure has a mounting recess in which said circuit board is positioned.

20. The circuit board arrangement according to claim 1, wherein said sensor element is a sensor element measuring an ambient parameter, or a temperature sensor element, or a gas sensor element, or a moisture sensor element or a pressure sensor element.

21. The circuit board arrangement according to claim 1, wherein said sensor element is fastened or soldered to said additional circuit board on a side facing away from said circuit board or on a side facing toward said circuit board.

22. The circuit board arrangement according to claim 7, wherein said sensor element is disposed in a region of said spacers.

23. The circuit board arrangement according to claim 22, wherein said sensor element is a temperature sensor element.

24. An energy storage device or an energy storage device for a vehicle, comprising:
a plurality of energy storage cells disposed in a row; and
a circuit board arrangement according to claim 1 provided on said energy storage device.
